(19) United States
(12) Patent Application Publication
(10) Pub. No.: US 2013/0146549 A1
(43) Pub. Date: Jun. 13, 2013

(54) SOLAR PANEL ASSEMBLY KIT AND METHOD OF ASSEMBLY

(71) Applicants: Kermit Wayne Winkelblech, Palos Park, IL (US); Steven R. Robbins, Stuart, FL (US)

(72) Inventors: Kermit Wayne Winkelblech, Palos Park, IL (US); Steven R. Robbins, Stuart, FL (US)

(73) Assignee: Superior Solar Systems, LLC, Longwood, FL (US)

(21) Appl. No.: 13/324,649

(22) Filed: Dec. 13, 2011

(51) Int. Cl. H01L 23/32; H01L 31/18

(52) U.S. Cl. 211/41.1; 29/890.033

(57) ABSTRACT

A frame for hanging a solar panel is provided. The frame may include: a first set of struts having holes corresponding to holes at the back of a solar panel and additional holes; and a second set of struts having holes corresponding to the additional holes in the first set of struts when one of the second set of struts is located behind and transverse to one of the first set of struts. A method of assembling a solar panel assembly may be provided. The method may include: positioning two solar panels side by side; aligning holes in a first set of struts with holes in the solar panels; attaching the first set of struts to the solar panels with fasteners; aligning holes in a second set of struts with holes in the first set of struts; attaching the second set of struts to the first set of struts; and attaching the second set of struts to a support rack.

### FIELD OF THE INVENTION

The present invention relates generally to solar panels. More particularly, the present invention relates to a support frame for mounting solar panels to a utility pole.

### BACKGROUND OF THE INVENTION

Solar panels have long been used to provide electricity. In a world having an ever increasing desire for energy and, in particular, clean energy or energy that does not require pollution of the environment in order to be generated is desired.

Solar energy provides clean energy and its use is being increased across the globe. In some instances, utility companies such as power companies are mounting solar panels on existing utility poles in order to increase the amount of energy a utility may supply. Such a move makes sense as the utility poles already carry power lines, other utilities, and/or lights and are already connected to the power grid. In some instances, when solar panels mounted on utility poles, the electricity generated by the solar panels is added to the energy grid. As can be appreciated, the solar panels must be mounted to the utility poles in a secure manner. Preferably, the mounting of the solar panels will withstand strong winds and other violent weather.

Because many utilities may have hundreds or even thousands of utility poles it is desired to provide a low cost mounting system to mount the solar panels to the utility poles.

Further, it is desirable to provide a mounting systems for the solar panels in a compact manner for shipping so that the frames may be quickly assembled and allowing rapid mounting of the solar panels to the utility pole.

Accordingly, it is desired to provide a method and apparatus that permits a solar panel or system of solar panels to be quickly and easily mounted to a mount or frame on a utility pole.

### SUMMARY OF THE INVENTION

The foregoing needs are met, to a great extent, by the present invention, wherein in one aspect an apparatus is provided that in some embodiments a method and apparatus is provided to allow systems or solar panels to be quickly and efficiently attached to a mounting frame on a utility pole.

In accordance with one embodiment of the present invention, a frame for hanging a solar panel is provided. The frame may include: a first set of struts having holes corresponding to holes at the back of a solar panel and additional holes; and a second set of struts having holes corresponding to the additional holes in the first set of struts when one of the second set of struts is located behind and transverse to one of the first set of struts.

In accordance with another embodiment of the present invention, a method of assembling a solar panel assembly may be provided. The method may include: positioning two solar panels side by side; aligning holes in a first set of struts with holes in the solar panels; attaching the first set of struts to the solar panels with fasteners; aligning holes in a second set of struts with holes in the first set of struts; attaching the second set of struts to the first set of struts; and attaching the second set of struts to a support rack.

In accordance with yet another embodiment of the present invention, a frame for hanging a solar panel may be provided. The frame may include: a first means for support having holes corresponding to holes at the back of a solar panel and additional holes; and a second mean of support having holes corresponding to the additional holes in the first means of support when one of the second means for support is located behind and across one of the first means for support.

There has thus been outlined, rather broadly, certain embodiments of the invention in order that the detailed description thereof herein may be better understood, and in order that the present contribution to the art may be better appreciated. There are, of course, additional embodiments of the invention that will be described below and which will form the subject matter of the claims appended hereto.

In this respect, before explaining at least one embodiment of the invention in detail, it is to be understood that the invention is not limited in its application to the details of construction and to the arrangements of the components set forth in the following description or illustrated in the drawings. The invention is capable of embodiments in addition to those described and of being practiced and carried out in various ways. Also, it is to be understood that the phraseology and terminology employed herein, as well as the abstract, are for the purpose of description and should not be regarded as limiting.

As such, those skilled in the art will appreciate that the conception upon which this disclosure is based may readily be utilized as a basis for the designing of other structures, methods and systems for carrying out the several purposes of the present invention. It is important, therefore, that the claims be regarded as including such equivalent constructions insofar as they do not depart from the spirit and scope of the present invention.

### BRIEF DESCRIPTION OF THE DRAWINGS

FIG. 1 is a rearview of a pair of solar panels having a portion of a support frame in accordance with an embodiment of the invention installed to the back of solar panels.

FIG. 2 is a side view of the solar panels and a portion of the support frame shown in FIG. 1.

FIG. 3 is a rearview of a pair of solar panels and a support frame attached to the solar panels in accordance with an embodiment of the invention.

FIG. 4 is a side view of the solar panels and support frame shown in FIG. 3.

FIG. 5 is a side view of the solar panels and support frame in close proximity to a mounting frame and utility pole in accordance with an embodiment of the invention.

FIG. 6 is a prospective view of the solar panels and support frame mounted to the mounting frame and utility pole in accordance with and embodiment of the invention.

### DETAILED DESCRIPTION

The invention will now be described with reference to the drawing figures, in which like reference numerals refer to like parts throughout. An embodiment in accordance with the present invention provides a support frame for attaching two or more solar panels together in a side by side arrangement. The support frame also provides a means for mounting a solar panel to a mounting frame on a utility pole.

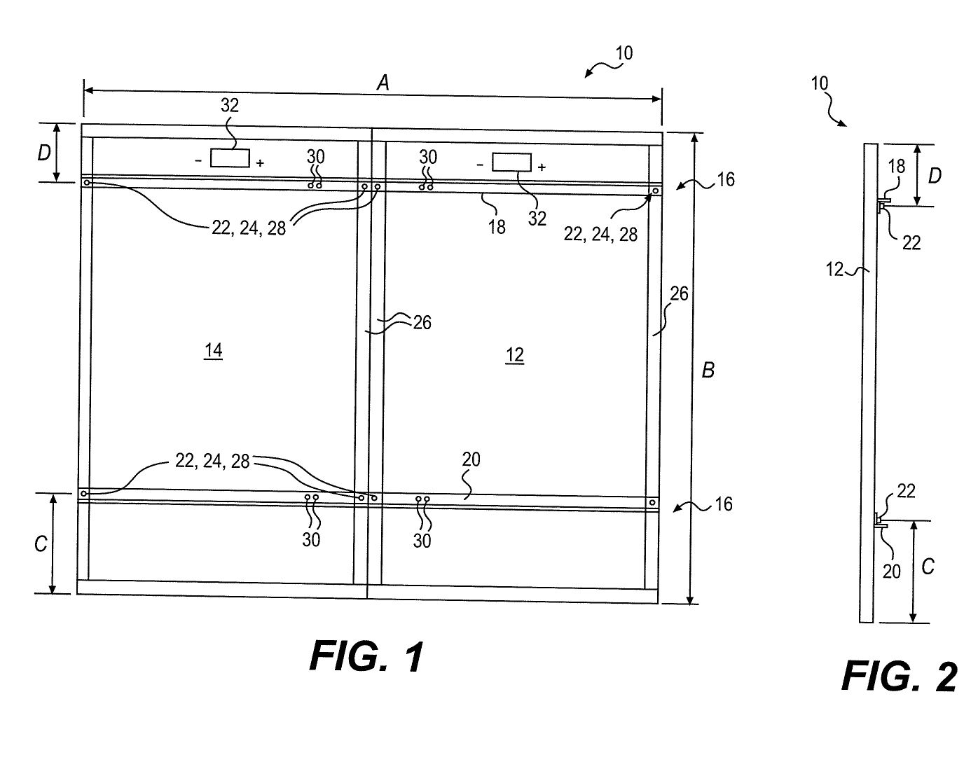

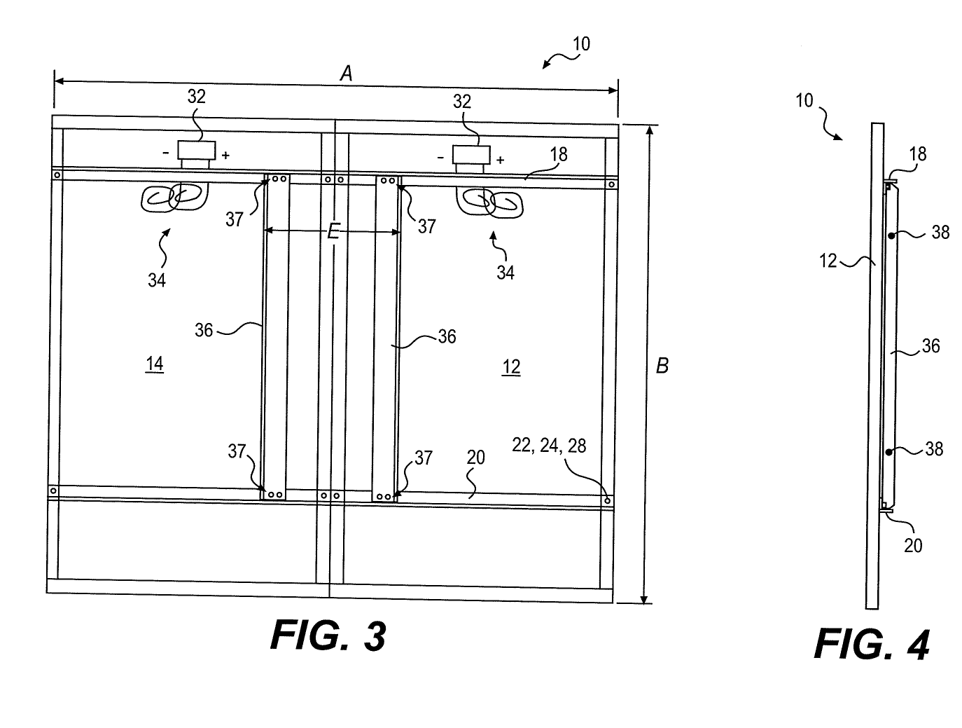

An apparatus in accordance with the invention is shown in FIG. 1. The solar panel assembly 10 includes two solar panels 12 and 14. The solar panels 12 and 14 are arranged in a side by side manner and are attached together by a support frame 16. Only a portion of the support frame 16 is shown in FIG. 1. The entire support frame 16 is shown in FIG. 3 and will be discussed later.

As shown in FIG. 1, a support frame 16 includes an upper horizontal strut 18 and a lower horizontal strut 20. As will be understood herein, the terms “horizontal” and “vertical” are intended be provide an orientation as shown in the FIGS. These terms are relative to orientations of certain embodiments shown in the figures and are not limiting.

A upper and lower struts 18 and 20 may be angled and have an L-shaped cross section. The horizontal struts 18 and 20 in embodiments of the invention may be made of 6063 aluminum architectural extension rails. Other materials may also be used.

In some embodiments of the invention, dimensions of the upper and lower horizontal struts 18 and 20 are 1⅝ inch×1⅝ inch× 3/16 inch. The upper and lower horizontal struts 18 and 20 may include holes 28 that can align with holes 24 already existing in the solar panels 12 and 14.

The upper and lower horizontal 18 and 19 may be connected via fasteners 22 inserted through the holes 28 in the horizontal strut 18 and 20 and holes 24 in the solar panel 12, 14. The holes 24 in the solar panel 12, 14 may be holes that are already existing in the solar panels 12 and 14 as made by the manufacturer.

In other embodiments of the invention, the holes 24 in the solar panel 12, 14 may be made in the solar panel 12, 14 at the point of constructing the assembly 10. The upper 18 and lower 20 horizontal struts may include additional holes 30. These additional holes 30 will be discussed in further detail later below.

In some embodiments of the invention, the fasteners 22 are placed through the holes 28 in the horizontal struts 18 and 20 and in the holes 24 in the solar panels 12 and 14. The fasteners 22 may include a stainless steel hex bolt, nut washers, and lock washers. In some embodiments of the invention, the dimension of the stainless steel hex bolt may be 1 inch× 5/16 inch. In other embodiments of the invention, fasteners 22 may be made of other materials than stainless steel and may have other dimensions. One of ordinary skill in the art after reviewing this disclosure will understand how to connect horizontal fasteners 18 and 20 to solar panels 12 and 14.

In some embodiments of the invention, the following dimensions may be used, however in other embodiments of the invention other dimensions may be used in accordance of the invention. For example, dimension A as illustrated in FIG. 1 may be about 78.25 inches, dimension B may be about 64.56 inches, dimension C may be about 14 inches and dimension D may be about 8 inches.

FIGS. 3 and 4 show the assembly 10 in a rear and side view. FIG. 3 also shows wires 34 extending from the terminal 32 for connection to the power grid to which the solar panels 12 and 14 will supply power.

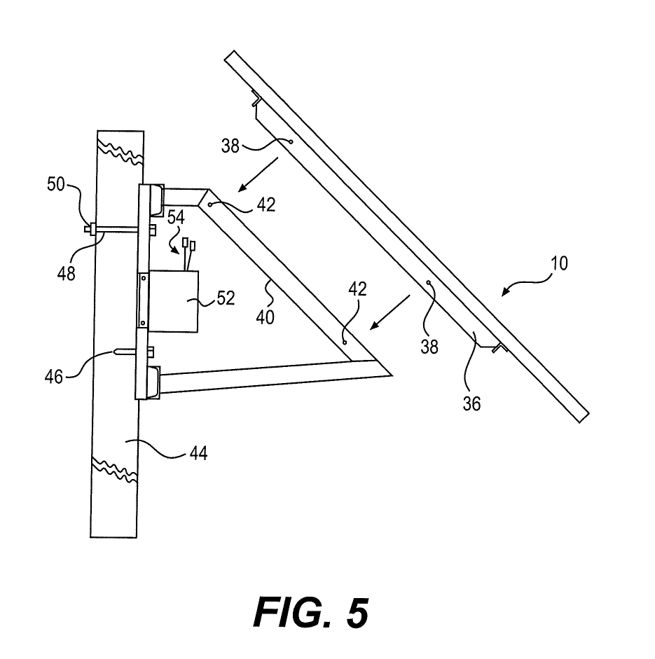

FIGS. 3 and 4 show vertical struts 36 attached to the upper 18 and lower 20 horizontal struts. The vertical struts 36 have holes 37 which align with the holes 30 (shown in FIG. 1) on the upper 18 and lower 20 horizontal struts. The vertical struts 36 also have holes 38 as shown in FIG. 4. to connect the assembly 10 to a mounting frame 40 as shown in FIG. 5.

According to some embodiments of the invention, the vertical struts 36 may be 3 inch×2 inch× 3/16 inch aluminum 6063 architectural extrusion rails having an L-shaped cross-section. The distance between the vertical struts 36 in some embodiments of the invention may be about 18 inches for example, 18.125 inches.

FIG. 5 illustrates the assembly 10 in close proximity to the mounting frame 40. Holes 38 on the vertical struts 36 are aligned with holes 42 in the mounting frame 40. The mounting frame 40 may be attached to a utility pole 44 by a lag screw 46 and/or a lag bolt 48 and a lag nut 50. A lag screw 46 may terminate within the utility pole 44 in contrast to a lag bolt 48 which may extend through the utility pole 44 and have a lag nut 50 attached.

A junction box 52 may have wire ends 54 for providing an electrical connection to the assembly 10 via the wires 34 as shown in FIG. 3.

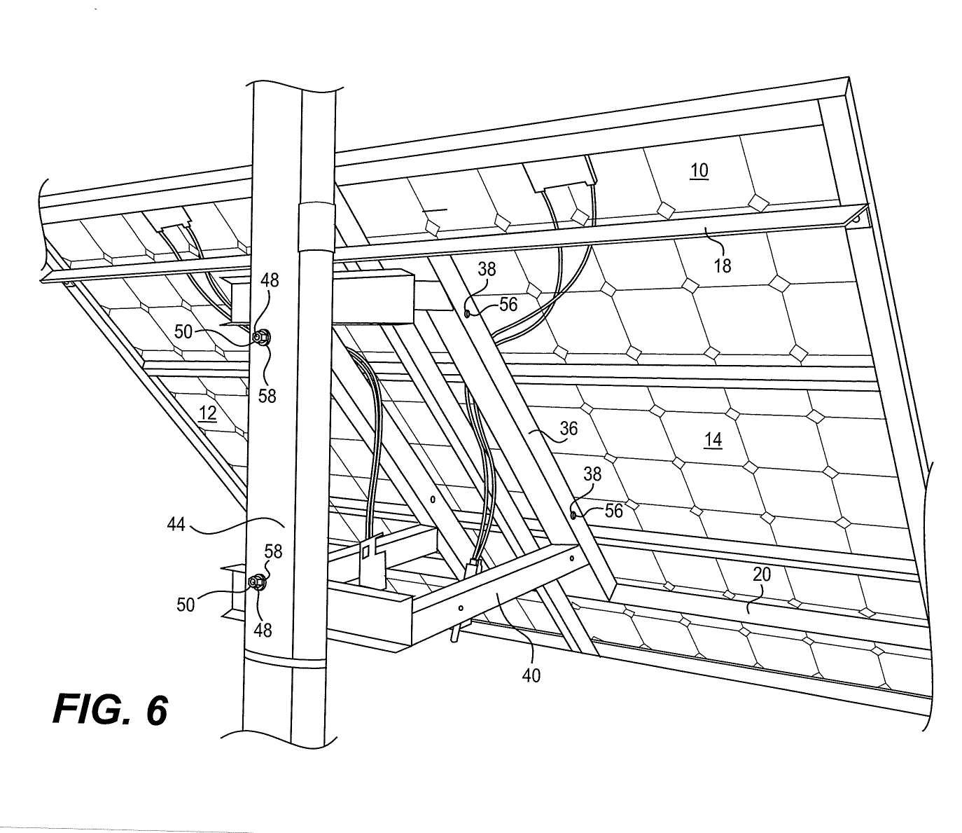

FIG. 6 illustrates the assembly 10 attached to the mounting frame 40. The vertical struts 36 are attached via fasteners 56 extending through the holes 38 in the vertical struts 36. The mounting frame 40 is attached to the utility pole 44 via lag bolts 48 extending through the utility pole 44. The lag bolts 48 have washers 58 located between the lag nut 50 and the utility pole 44. In comparing FIGS. 5 and 6, it is shown that the mounting frame 40 can be attached to utility pole 44 either by lag screw 46 or lag bolt 48 or a combination of the two. One of ordinary skill in the art may chose how the mounting frame 40 is attached to the utility pole 44. Furthermore, many of the mounting frames 40 may be known in the art. Currently, in the whole 38 in the vertical struts 36 are located to correspond to holes 42 found in mounting frame 40.

The many features and advantages of the invention are apparent from the detailed specification, and thus, it is intended by the appended claims to cover all such features and advantages of the invention which fall within the true spirit and scope of the invention. Further, since numerous modifications and variations will readily occur to those skilled in the art, it is not desired to limit the invention to the exact construction and operation illustrated and described, and accordingly, all suitable modifications and equivalents may be resorted to, falling within the scope of the invention.

What is claimed is:

1. A frame for hanging a solar panel comprising:
a first set of struts having holes corresponding to holes at the back of a solar panel and additional holes; and
a second set of struts having holes corresponding to the additional holes in the first set of struts when one of the second set of struts is located behind and transverse to one of the first set of struts.

2. The frame of claim 1, wherein the first and second sets of struts are angles.

3. The frame of claim 1, wherein the first and second sets of struts are metal.

4. The frame of claim 3, wherein the metal is aluminum or stainless steel.

5. The frame of claim 1, wherein the first set of struts are about the same length as the width of two solar panels located side by side.

6. The frame of claim 1, wherein the second set of struts are shorter and wider than the first set of struts.

7. The frame of claim 6, wherein the second set of struts have two holes located side by side at each end of the strut and the two holes are spaced apart at the same distance as the other holes in the first set of struts.

8. The frame of claim 7, wherein the second set of struts are angled and have more holes on the member at a right angle to the member where the two holes are located.

9. A method of assembling a solar panel assembly comprising:
positioning two solar panels side by side;
aligning holes in a first set of struts with holes in the solar panels;
attaching the first set of struts to the solar panels with fasteners;
aligning holes in a second set of struts with holes in the first set of struts;
attaching the second set of struts to the first set of struts; and
attaching the second set of struts to a support rack.

10. The method of claim 9, wherein the first set of struts and the second set of struts are transverse with respect to each other.

11. The method of claim 9, wherein some of the holes in the first set of struts align with holes placed in the solar panels by the manufacturer of the solar panel.

12. The method of claim 9, wherein each set of struts has two struts.

13. The method of claim 9, wherein one of the first set of struts is placed about 8 inches from an end of the solar panels.

14. The method of claim 13, wherein the other strut of the first set of struts is placed about 14 inches from the other end of the solar panel.

15. The method of claim 14, wherein the second set of struts are placed about 18 inches from each other.

16. The method of claim 15, wherein the second set of struts are place about 18.125 inches from each other.

17. The method of claim 9, wherein the fasteners include a hex bolt, a nut, a washer and a lock washer.

18. The method of claim 9, wherein the fasteners are stainless steel.

19. A frame for hanging a solar panel comprising:
a first means for support having holes corresponding to holes at the back of a solar panel and additional holes; and
a second means for support having holes corresponding to the additional holes in the first means of support when one of the second means for support is located behind and across one of the first means for support.

20. The frame of claim 19, wherein the first and second means for support are L-shaped brackets.
